(19) United States
(12) Patent Application Publication
(10) Pub. No.: US 2021/0234091 A1
(43) Pub. Date: Jul. 29, 2021

(54) MAGNETIC MEMORY AND METHOD OF FABRICATION

(71) Applicant: APPLIED Materials, Inc., Santa Clara, CA (US)

(72) Inventors: Jong Mun Kim, Sunnyvale, CA (US); Mang-Mang Ling, Santa Clara, CA (US); Soham Asrani, Santa Clara, CA (US); Lin Xue, Santa Clara, CA (US); Chentsau Chris Ying, Santa Clara, CA (US); Srinivas D. Nemani, Santa Clara, CA (US); Ellie Y. Yieh, Santa Clara, CA (US)

(73) Assignee: APPLIED Materials, Inc., Santa Clara, CA (US)

(21) Appl. No.: 16/752,013

(22) Filed: Jan. 24, 2020

(51) Int. Cl. H01L 43/12; H01L 43/10

(52) U.S. Cl. CPC H01L 43/12; H01L 43/10

(57) ABSTRACT

A method of etching a layer stack. The method may include providing a substrate in a process chamber, the substrate comprising an array of patterned features, arranged within a layer stack, the layer stack including at least one metal layer, and directing an ion beam to the substrate from an ion source, wherein the ion beam causes a physical sputtering of the at least one metal layer. The method may include directing a neutral reactive gas directly to the substrate, separately from the ion source, wherein the neutral reactive gas reacts with metallic species generated by the physical sputtering of the at least one metal layer.

### FIELD

Embodiments relate to the field of non-volatile storage. More particularly, the present embodiments relate to a magnetic memory and related fabrication techniques.

### BACKGROUND

The fabrication of electrical, electronic, or optical devices, among other devices, may entail etching of various materials or layers, including insulators, semiconductors and metals. For certain devices, including those formed with metallic layers, patterning of device features may involve etching of metals using sputter etching. As an example, magnetic random access memory entails to the formation of memory cells in an array of small features arranged as a stack of layers. Unlike some random access memory chip technologies, data in MRAM devices is not stored as electric charge or current flows, but rather by magnetic storage elements. Moreover, unlike dynamic random access memory, MRAM devices are non-volatile and do not require refreshing to preserve the memory state of a cell.

An MRAM device may include storage elements formed from two ferromagnetic plates, each of which can hold a magnetic field, separated by a thin insulating layer. Patterning of MRAM devices such as STT-MRAM may take place by defining a patterned mask formed on top of a stack of layers that contains at least two magnetic layers separated by an insulating layer. The patterned mask typically contains isolated mask features that expose regions of the substrate that lie between the mask features, which exposed regions are subsequently etched away through the stack of layers that constitute a memory device. After etching, isolated islands or pillars remain, which pillars constitute individual memory bits. While patterning by ion etching of such memory devices is useful, many materials used in the stack of layers are difficult to etch using reactive ion etching. Moreover, while sputter etching with a non-reactive ion species may be capable of removing various metal layers, the sputtered metal material may be non-volatile and may tend to redeposit locally, such as on sidewalls of pillars. As such, redeposited metallic material may create unwanted electrical shorting between different layers of the memory device. With respect to these and other considerations the present disclosure is provided.

### SUMMARY

Embodiments are directed to methods for improved etching of layer stacks including a metal layer. In one embodiment, a method of etching a layer stack may include providing a substrate in a process chamber, the substrate comprising an array of patterned features, arranged within a layer stack, the layer stack including at least one metal layer, and directing an ion beam to the substrate from an ion source, wherein the ion beam causes a physical sputtering of the at least one metal layer. The method may include directing a neutral reactive gas directly to the substrate, separately from the ion source, wherein the neutral reactive gas reacts with metallic species generated by the physical sputtering of the at least one metal layer.

In another embodiment, a method of etching a magnetic memory may include providing a substrate in a process chamber, the substrate comprising an array of patterned features, arranged within a magnetic layer stack, the magnetic layer stack including at least one metal layer. The method may include directing an ion beam to the substrate from an ion source, wherein the ion beam causes a physical sputtering of the at least one metal layer; and directing a neutral reactive gas directly to the substrate, separately from the ion source, wherein the neutral reactive gas reacts with metallic species generated by the physical sputtering of the at least one metal layer.

In a further embodiment, a method of etching a magnetic memory may include providing a substrate in a process chamber, the substrate comprising an array of patterned features, arranged within a magnetic layer stack, the magnetic layer stack including at least one metal layer. The method may include extracting an ion beam and directing the ion beam to the substrate from an ion source, wherein the ion beam causes a physical sputtering of the at least one metal layer, at a non-zero angle of incidence with respect to a perpendicular to a main plane of the substrate. The method may further include directing a neutral reactive gas directly to the substrate, separately from the ion source, and concurrently with the directing the ion beam, wherein the neutral reactive gas reacts with metallic species generated by the physical sputtering of the at least one metal layer.

### BRIEF DESCRIPTION OF THE DRAWINGS

FIGS. 1A-1D illustrate a side view of processing of a device structure according to at least one embodiment of the disclosure;

FIGS. 1E-1H illustrate a side view of processing of a device structure according to at least one additional embodiment of the disclosure;

FIG. 2 presents an exemplary MRAM array;

FIG. 2A presents an exemplary MRAM layer stack at an early stage of etching according to embodiments of the disclosure;

FIG. 2B presents the MRAM layer stack of FIG. 2A after completion of etching according to embodiments of the disclosure;

FIG. 3 presents an exemplary system for etching a layer stack;

FIG. 4A presents a side view of exemplary system for etching a layer stack;

FIG. 4B presents a bottom plan view of a portion of the system of FIG. 4A, according to one embodiment; and

FIG. 5 presents an exemplary process flow.

### DETAILED DESCRIPTION

The present disclosure will now be described more fully hereinafter with reference to the accompanying drawings, in which some embodiments are shown. The subject of this disclosure, however, may be embodied in many different forms and should not be construed as limited to the embodiments set forth herein. Rather, these embodiments are provided so that this disclosure will be thorough and complete, and will fully convey the scope of the subject of this disclosure to those skilled in the art. In the drawings, like numbers refer to like elements throughout.

To solve the deficiencies associated with the methods noted above, novel techniques for patterning a substrate are introduced. In particular, the present disclosure focuses on techniques involving a combination of physical ion beam sputtering to etch a metallic layer in a layer stack, and local reaction of metallic etched species deposited on sidewalls of the layer stack to ensure that the sidewalls remain non-conductive

As detailed below, the present embodiments address challenges for patterning complex layer stacks that include metal layers, in order to form devices such as MRAM devices. In some embodiments, a combination of ion beam sputtering and reactive gas species may be employed to etch some or all the metal layers in a magnetic tunnel junction (MTJ) stack including MgO layers in a continuous fashion. For the purposes of illustration, in some embodiments the combination of layers used to form a non-volatile memory may be depicted for specific MRAM device configurations. However, the present embodiments are not limited to any specific combination of layers to be used to fabricate an MRAM cell. In various embodiments, a layer stack to form an MRAM cell may be fabricated upon a substrate base consistent with known techniques. The term “substrate base,” refer herein to any substrate that contains any set of layers and/or structures upon which a layer stack to form an MRAM cell is formed. As will be apparent to those of ordinary skill in the art, the substrate underlayer, or base, need not be planar and may include multiple different structures on the surface. However, in the FIGs. to follow, the portions of a substrate base upon which base a layer stack of the MRAM device is formed is depicted as planar.

In various embodiments, processes for patterning magnetic storage cells may involve the physical sputter etching of at least one layer of a layer stack provided on a substrate, using a patterned hard mask, to define an array of magnetic or MRAM storage elements or MRAM cells. In various embodiments, the MRAM cell may be fabricated from a stack of layers (also referred to herein as a “layer stack”) that is the same or similar to layer stacks of known MRAM devices. According to various embodiments, a neutral reactive gas may be directed to the substrate in conjunction with the physical sputtering of the layer stack. The neutral reactive gas may directed concurrently with an ion beam that is used to sputter etch the layer stack, for example. The neutral reactive gas may be provided separately from an ion beam to the substrate, in a manner where the neutral reactive gas reacts locally with metallic species, such as redeposited metallic atoms or layers forming on portions of an MRAM element, such as on sidewalls.

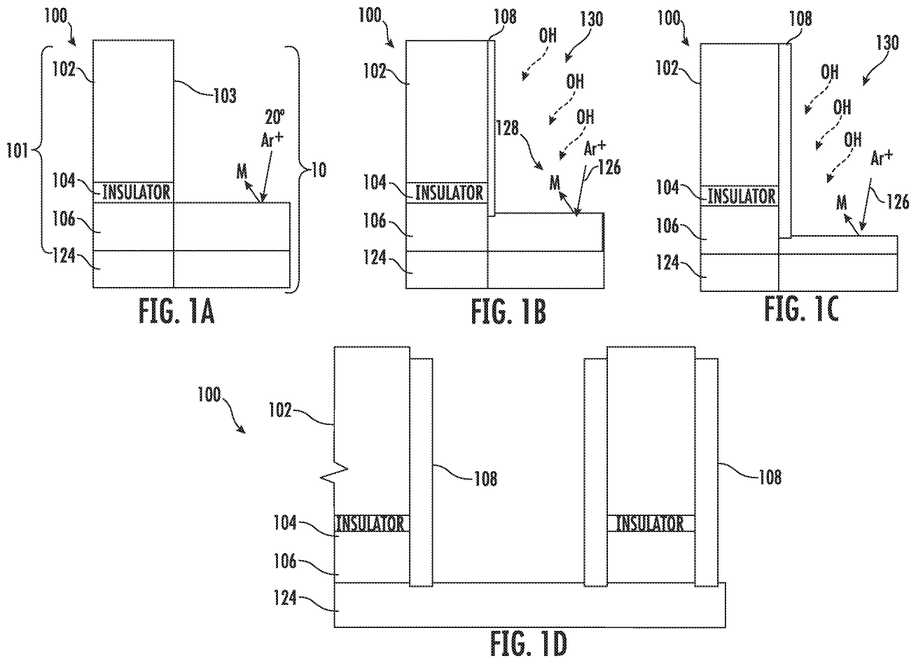

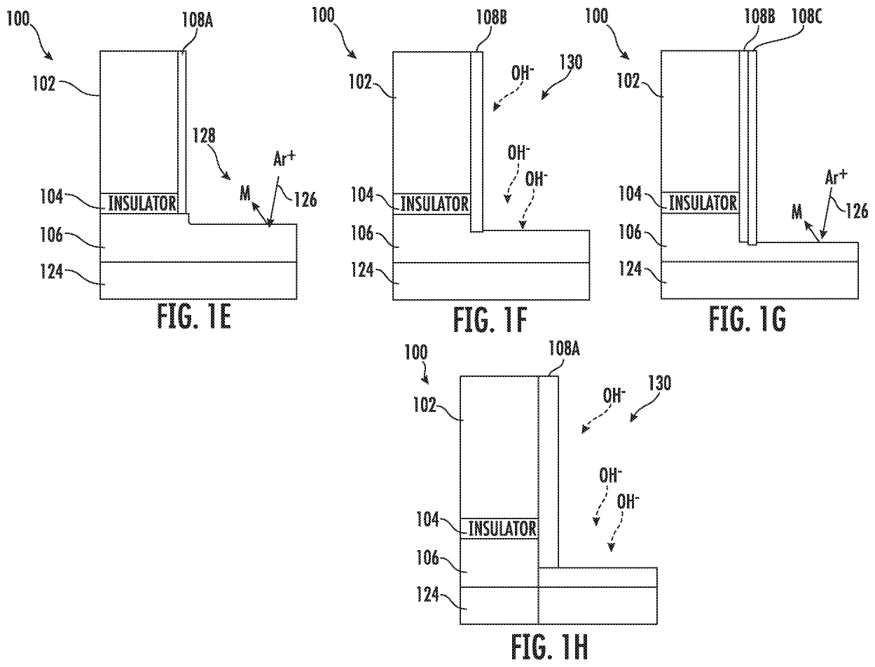

FIGS. 1A, 1B, 1C and 1D illustrate a side view of processing of a device structure 100 according to embodiments of the disclosure. In various embodiments, the device structure 100 may represent an MRAM device, during processing to form MRAM cells. The device structure 100 in FIG. 1A includes a layer stack 101, disposed on a substrate base 124 of a substrate 10. In some non-limiting embodiments, the substrate base 124 may be a silicon wafer, and may include a plurality of layers, including a silicon oxide layer, for example. The layer stack 101 at the stage of FIG. 1A has been partially etched to form a patterned feature 103 in an upper portion 102, while a lower portion 106 is unetched. To complete formation of a device such as a memory cell, the lower portion 106 may be etched until the substrate base is reached. Notably, in a device such as an MRAM array, a plurality of patterned features 103 may be formed, to serve as memory cells, for example. Said differently, at the stage of FIG. 1A, the substrate base 124 may include an array of patterned features 103, arranged in a layer stack 101, which layer stack was initially unpatterned. In various embodiments, the array of pattern features 103 may be characterized by a pitch ranging from greater than 500 nm to less than 40 nm, with an aspect ratio (height/width) ranging from less than 1 to greater than 5/1.

In the example of FIG. 1A, the upper portion 102 is separated from the lower portion 106 by an insulator layer 104. In embodiments of an MRAM device, the insulator layer 104 may be a magnesium oxide (MgO) layer, separating portions of a magnetic stack. For example, in known MRAM devices, an upper MgO layer may separate an upper contact from a free layer of a magnetic tunnel junction device structure, while a lower MgO layer may separate the free layer from a reference layer, that lies subjacent the lower MgO layer. Notably, the reference layer and free layer in an MTJ device may include multiple metal layers, as in known in the art.

At the stage of etching of the patterned feature 103 shown in FIG. 1A, the upper portion 102 and insulator layer 104 have been etched. In various embodiments, the upper portion 102 includes a mask layer, which layer may be patterned according to known techniques to serve as a mask for etching subjacent layers. In addition, the upper portion 102 may include upper contact layers, free layers, insulator layers, and so forth. In some embodiments, the etching of the upper portion 102 may be performed using any combination of suitable etch procedures, to etch the various constituent layers of the upper portion 102. Such etch procedures may include sputter etching, reactive ion etching, and so forth.

To complete the etching of the layer stack 101, in accordance with embodiments of the present disclosure, a novel etch operation may be performed in order to maintain electrical isolation between the upper portion 102 and lower portion 106. For example, in order to maintain electrical isolation between a reference layer and a free layer of an MRAM device, maintaining of insulating properties of an insulator layer separating the reference layer and free layer is useful. In embodiments where the lower portion 106 includes a lower contact and a reference layer, the lower portion 106 represents multiple metallic layers, where at least some of the layers may be difficult to etch using known reactive ion etching techniques. As such sputter etching may constitute a more suitable approach, since most if not all materials may be removed by physical sputtering using the appropriate sputtering species.

Turning now to FIG. 1B there is shown one aspect of an etching procedure according to embodiments of the disclosure. The instance in FIG. 1B takes place after the instance of FIG. 1A, where the layer stack 101 was previously etched through the insulator layer 104. In FIG. 1B, an ion beam 126 is directed to the substrate 10. In addition, a neutral reactive gas 130 is provided directly to the substrate 10, and concurrently with the ion beam 126. The ion beam 126 may be provided from an ion source, while the neutral reactive gas 130 is provided separately from the ion source. As such, interaction of the ion beam 126 and the neutral reactive gas 130 may be suppressed in comparison to arrangements where an ion beam and reactive gas are provided from a common source. The ion beam 126 may be formed of a suitable species to generate sputter etching of the lower portion 106, which portion may include at least one metal layer, as noted above. Non-limiting examples of suitable species for forming ion beam 126 include argon (Ar), krypton (Kr), or other inert gas species. Non-limiting examples of suitable species for the neutral reactive gas 130 include a molecule having a hydroxyl group, such as molecules represented by the formula R—OH, where R is given by CₓH₍₂ₓ₎₊₁. In particular embodiments, the value of x ranges from 1 to 3, meaning the neutral reactive gas 130 is methanol, propanol, or butanol, or a combination thereof.

During the operation of FIG. 1B, the ion beam 126 may cause sputtering of the lower portion 106, and may generate metallic species 128 that are ejected into the gas phase, as shown. The metallic species 128 may result from one or more metal layers disposed in the lower portion 106, including layers of a lower contact or layers of a reference layer of an MTJ structure. Such metallic species in general may be non-volatile and may tend to redeposit locally on surfaces of the patterned features 103. These surfaces include sidewalls of the patterned features 103. While the metallic species 128 may deposit on such sidewalls, rather than forming a conductive layer on the sidewalls, the provision of the reactive neutral gas 130 may provide reaction products to react with the metallic species 128, forming the sidewall insulator layer 108 along the sidewall of layer stack 101, as shown. As an example, methanol may readily react with a metallic species such as tantalum to oxidize the tantalum and to form a tantalum oxide layer than is an electrical insulator. As such, the formation of the sidewall insulator layer 108 may prevent electrical shorting between lower portion 106 and upper portion 102 of the patterned features 103.

At the instance of FIG. 1B just an upper part of the lower portion 106 has been etched. In FIG. 1C, a later instance is shown where the lower portion 106 is further etched. More metallic species may have deposited on the sidewalls of patterned features 103, which species are oxidized by the reactive neutral gas 130. FIG. 1D shows a later instance after completion of etching of the lower portion 106, where a thicker sidewall insulator layer 108 has formed.

In other embodiments, an ion beam and neutral reactive gas may be directed to a substrate in an alternating fashion, as shown in FIGS. 1E-1H. In FIG. 1E the ion beam 126 sputter etches a top part of the lower portion 106, causing redeposition of a sidewall metal layer 108A. In FIG. 1F, the neutral reactive gas 130 is provided to react with the sidewall metal layer 108A, forming the sidewall insulator layer 108B. Notably, the thickness of the sidewall metal layer 108A may be maintained below a given amount, such as below one nanometer, or below 0.5 nm to ensure appropriate oxidation of the sidewall metal layer 108A. In FIG. 1G the ion beam 126 is directed to the patterned feature 103 once more, causing further etching of the lower portion 106 and formation of a sidewall metal layer 108C on the sidewall insulator layer 108B. In FIG. 1H, the neutral reactive gas 130 is again directed to the patterned feature 103, in the absence of ion beam 126, resulting in the formation of a sidewall insulator layer 108D. This process may be continued until completion of etching of the lower portion 106 to form a structure similar to the structure of FIG. 1D.

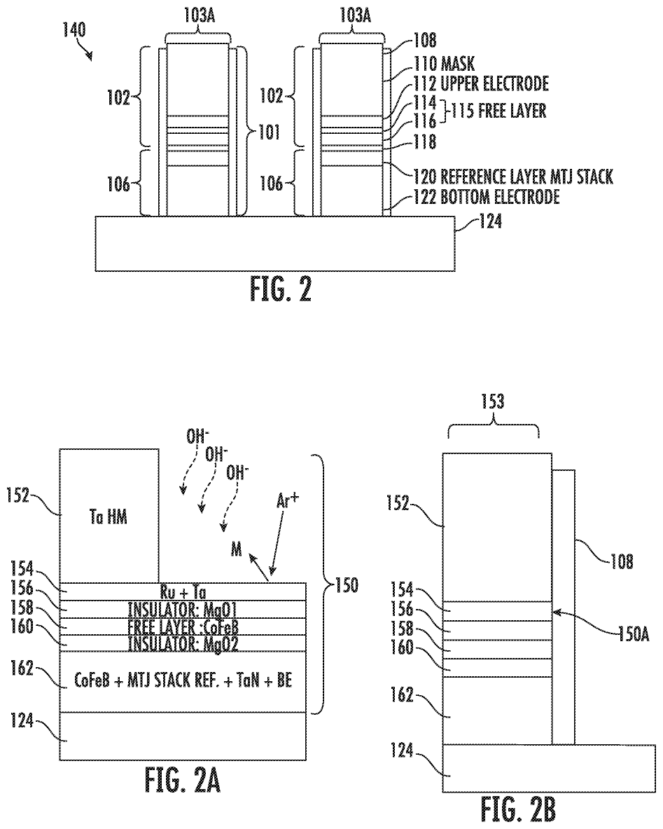

Turning now to FIG. 2 an exemplary MRAM array 140 is shown. The MRAM array 140 may include a plurality of MRAM cells 103A, formed from complete etching of the layer stack 101, described previously. The upper portion 102 in this embodiment may include a mask 110, and upper electrode layer 112. The upper portion 102 may also include a free layer 115, which layer may include an MgO layer 114 and magnetic layer stack 116. The lower portion 106 in this embodiment may include a reference MTJ stack of magnetic layers, shown as reference layer 120, separated from the upper portion 102 by an MgO layer 118. A sidewall insulator layer 108 has been formed, in accordance with embodiments of the disclosure, as previously discussed. The sidewall insulator layer 108 helps ensure that no electrical shorting takes place between the upper portion 102 and lower portion 106.

FIG. 2A presents an exemplary MRAM layer stack at an early stage of etching according to embodiments of the disclosure. In this example, a layer stack 150 includes a Ta hard mask layer 152, which layer has already been etched and patterned to form the basic size and shape of an MRAM cell 153 to be formed, as shown in FIG. 2B. The Ta hard mask layer 152 may constitute an upper portion of the layer stack 150, which upper portion may be patterned and etched according to any suitable method.

In particular, FIG. 2B presents the MRAM layer stack of FIG. 2A after completion of etching according to embodiments of the disclosure. The layer stack 150 includes an Ru+Ta set of layers shown as layer 154, subjacent to the Ta hard mask layer 152. A top MgO layer 156 is disposed immediately subjacent the layer 154, while a free layer 158 is disposed subjacent the top MgO layer 156. In this embodiment, the free layer 158 may be formed of an assembly of Co, Fe, and B. A lower MgO layer 160 is disposed subjacent the free layer 158. Subjacent to the lower MgO layer 160 is a lower layer stack 162. The lower layer stack 162 may be formed of a plurality of individual layers, including a CoFeB layer, MTJ layer stack, a TaN layer, and a bottom electrode layer. The layer 154, top MgO layer 156, free layer 158, lower MgO layer 160, and lower layer stack 162 may be deemed to constitute a lower portion of the layer stack 150 in some embodiments.

According to some embodiments of the disclosure, the aforementioned processes disclosed with respect to FIGS. 1A-1H may be used to etch one layer, a plurality of layers, or all layers of the lower layer stack, described above. For example, a continuous process may be performed using an ion beam sputter etching in combination with reactive gas provided directly to the device stack 100A, to etch all the layers that are subjacent to the Ta hard mask layer 152, with the resultant structure as shown in FIG. 2B. In FIG. 2B, a sidewall insulator layer 108 has been formed, which layer may result from oxidation of various metallic materials that are sputtered from the individual metal-containing layers of the layer stack 150, and are redeposited on sidewalls 150A. As such, the sidewall insulator layer 108A prevents electrical shorting between any of the various metallic layers of the layer stack 150 that are separated by insulating layers (MgO) from one another.

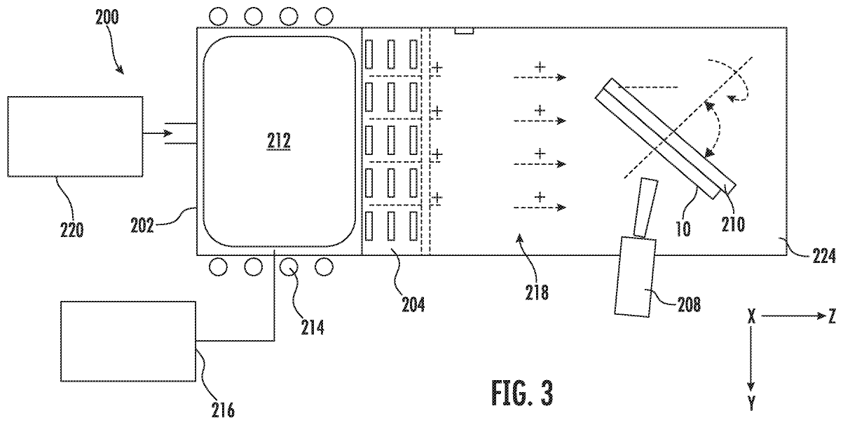

FIG. 3 presents an exemplary system, for etching a layer stack in accordance with embodiments of the disclosure. The system 200 may include a plasma chamber 202, to generate a plasma 212, for processing a substrate 10. The system 200 may further include an applicator 214 and power source 216, such as an RF induction or RF capacitor or other power source, to provide power to generate the plasma 212. The system 200 may further include an extraction assembly 204, disposed along a side of the plasma chamber 202, to extract an ion beam 218 from the plasma 212. The system 200 may include a gas source 220, to provide gas for forming the plasma 212. Non-limiting examples of suitable for forming ions for ion beam 218 include argon (Ar), krypton (Kr), or other inert gas species. The system 200 may include a substrate stage 210, disposed in a processing chamber 224, and having the ability to rotate along one or more axes, such as the X-axis of the Cartesian coordinate system shown. As such the ion beam 218 may be directed to the substrate 10 along a trajectory that is perpendicular to the plane of the substrate 10 or along a trajectory that forms a non-zero angle of inclination with respect to the perpendicular. The ion beam 218 may be suitable for sputter etching at least one layer of a layer stack as previously discussed, including metallic layers that are difficult to etch by reactive ion etching. In some embodiments, the value of the non-zero angle of inclination may vary up to 85 degrees, while in particular embodiments the value may range between 5 degrees and 35 degrees. By providing the ion beam 218 at a non-zero angle with respect to perpendicular, the ion beam 218 may better etch residue from sidewalls of device features that are being formed, so as to reduce contamination.

As further shown in FIG. 3, the system 200 may include a reactive gas source 208, disposed to direct a reactive gas 222 directly to the substrate 10, without passing through the plasma chamber 202. As such, the reactive gas 222 may arrive at the substrate 10 as a neutral reactive gas, which gas may dissociate into a hydroxide radical (OH) in the vicinity of the substrate 10, to provide a source to react with metal atoms that are sputtered by ion beam 218, generating an oxide layer on surfaces where the metal atoms condense. Because the reactive gas 222 is provided separately from the plasma chamber 202 to the substrate 10, the reactive gas 222 does not excessively dissociate into oxygen radicals and other reactive species before encountering the substrate 10. Thus, the reactive gas 222 does not provide a source of radical species that unduly attack metal layers in a layer stack including magnetic materials, while still providing a source of hydroxide ions to oxidize sputtered metal atoms that may condense upon sidewalls of a device structure being etched, as discussed above.

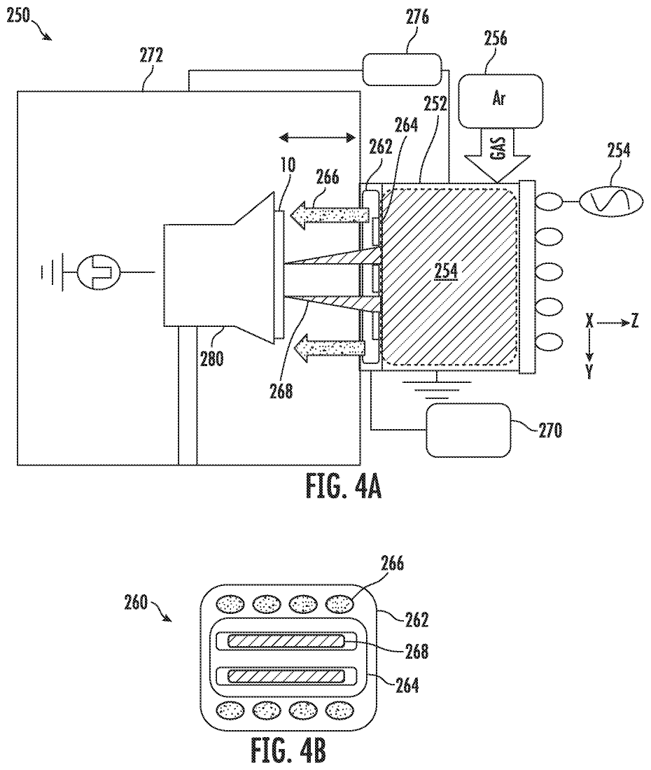

FIG. 4A depicts a side view of a processing apparatus 250 during ion beam processing of a substrate, in accordance with embodiments of the present disclosure. FIG. 4B depicts a bottom view of a portion of the processing apparatus of FIG. 4A. As to the general features of the processing apparatus 250, this apparatus represents a processing apparatus for novel etching processing of a substrate, such as a substrate having patterned features arranged in a layer stack, including MRAM devices. The processing apparatus 250 may be a plasma-based processing system having a plasma chamber 252 for generating a plasma 258 therein by any convenient method as known in the art. A power supply 254, may, for example, be an RF power supply to generate the plasma 258. An extraction assembly 260 may be provided as shown, and described further below.

As further shown in FIG. 4A, a gas source 256 may be provided to direct gas directly into the plasma chamber 252, such as an inert gas. A gas source 270 may be disposed to provide a reactive gas into a gas distribution assembly 262, where the gas distribution assembly 262 is not directly coupled through any openings to the plasma chamber 252. As shown in FIG. 4B, the gas distribution assembly may include a plurality of openings to direct reactive gas 266 to a substrate stage 280 that is disposed in a processing chamber 272. As such, reactive gas that is provided from gas source 270 travels to the substrate stage 280 without interaction with the plasma 258.

In the example shown in FIG. 4B, the extraction assembly 260 may include an extraction system 264 to define one or more ion beams, shown as ion beams 268. The ion beams 268 may be extracted when a voltage difference is applied using a bias voltage source, shown as bias supply 276, between the plasma chamber 252 and substrate stage 280 as in known systems. The bias supply 276 may be coupled to the process chamber 272, for example, where the process chamber 272 and substrate stage 280 are held at the same potential. In various embodiments, the ion beams 268 may be extracted as a continuous beam or as a pulsed ion beam as in known systems. For example, the bias supply 276 may be configured to supply a voltage difference between plasma chamber 252 and process chamber 272, as a pulsed DC voltage, where the voltage, pulse frequency, and duty cycle of the pulsed voltage may be independently adjusted from one another. When configured in the shape of a ribbon beam as in FIG. 4B, these angled ion beams may expose an entirety of the substrate 10 to sputter etching by the ion beams 268, by scanning the substrate stage 280 along a scan direction, such as along the Y-axis.

In various embodiments, the value of the non-zero angle of incidence for ion beams 268 may vary from 5 degrees to 45 degrees, while in some embodiments the value may range between 10 degrees and 20 degrees. The embodiments are not limited in this context.

Because the reactive gas 266 is provided to the processing chamber 272 separately from the plasma chamber 252 to the substrate 10, the reactive gas 266 does not excessively dissociate into oxygen radicals and other reactive species before encountering the substrate 10. Thus, the reactive gas 266 does not provide a source of radical species that unduly attack metal layers in a layer stack including magnetic materials, while still providing a source of hydroxide ions to oxidize sputtered metal atoms that may condense upon sidewalls of a device structure being etched, as discussed above.

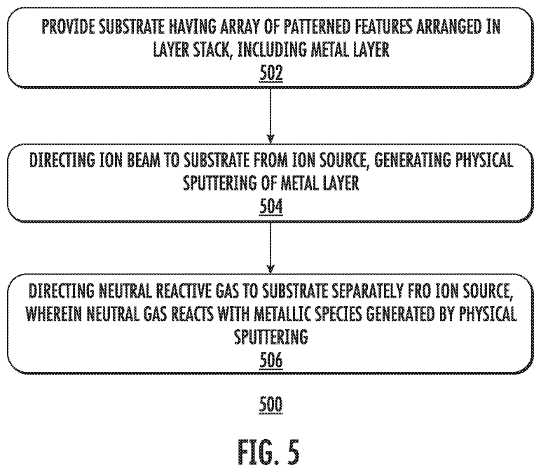

FIG. 5 depicts an exemplary process flow 500, according to one embodiment of the disclosure. At block 502, a substrate is provided in a processing chamber, having an array of patterned features that are arranged in a layer stack, where the layer stack includes at least one metal layer. In some examples, the layer stack may form a sequence of layers for forming an MRAM device. The metal layer may be a Ta layer, TaN layer, a magnetic layer, Ru, or other metal layer. At block 504, an ion beam is directed to the substrate from an ion source, generating physical sputtering of the metal layer. The physical sputtering of the metal layer may etch the metal layer as part of etching the layer stack to form a patterned structure, such as an MRAM cell. During the etching of the metal layer, metal atoms sputtered from the metal layer may redeposit on surfaces of a patterned structure being etched, including upon sidewalls. A non-limiting example of redeposited material includes redeposited tantalum or other metal.

At block 506 a neutral reactive gas is directed to the substrate separately from the ion source, where the neutral gas reacts with metallic species directing neutral reactive gas to substrate separately from ion source, wherein neutral gas reacts with metallic species that are generated by physical sputtering of the metal layer. The neutral gas may dissociate into OH fragments in the vicinity of the substrate within a processing chamber. As such, the OH fragments may react to form an oxide layer, such as a sidewall oxide layer that is an electrical insulator, ensuring metal layers in different regions of the layer stack are not electrically shorted to one another.

The present embodiments provide various advantages over known processing approaches to pattern layer stacks including hard-to-etch metal layers. One advantage lies in the ability to facilitate etching of complex layer stacks by use of physical sputtering of any layer that is otherwise difficult to etch by reactive ion etching. Another advantage is the ability to ensure separate metal layers within a layer stack are not electrically shorted to one another by virtue of redeposition of metallic material during sputter etching of a metal layer.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are in the tended to fall within the scope of the present disclosure. Furthermore, the present disclosure has been described herein in the context of a particular implementation in a particular environment for a particular purpose, while those of ordinary skill in the art will recognize the usefulness is not limited thereto and the present disclosure may be beneficially implemented in any number of environments for any number of purposes. Thus, the claims set forth below are to be construed in view of the full breadth and spirit of the present disclosure as described herein.

What is claimed is:

1. A method of etching a layer stack, comprising:
providing a substrate in a process chamber, the substrate comprising an array of patterned features, arranged within a layer stack, the layer stack including at least one metal layer;
directing an ion beam to the substrate from an ion source, wherein the ion beam causes a physical sputtering of the at least one metal layer; and
directing a neutral reactive gas directly to the substrate, separately from the ion source, wherein the neutral reactive gas reacts with metallic species generated by the physical sputtering of the at least one metal layer.

2. The method of claim 1, wherein the neutral reactive gas reacts with redeposited metallic material that is sputtered from the at least one metal layer, and redeposited on a sidewall of the array of patterned features, wherein the redeposited metallic material is oxidized to form an insulating coating.

3. The method of claim 1, wherein the array of patterned features comprises a magnetic random access memory (MRAM).

4. The method of claim 3, wherein the at least one layer comprises tantalum, wherein the neutral reactive gas reacts with redeposited tantalum that is sputtered by the ion beam, and redeposited on a sidewall of the array of patterned features, wherein the redeposited tantalum to form a tantalum oxide coating.

5. The method of claim 4, wherein the layer is disposed subjacent a MRAM layer stack including at least one insulator layer.

6. The method of claim 1, wherein the layer stack comprises:
a hard mask layer and a set of subjacent layers, the set of subjacent layers comprising:
a set of metal layers, disposed immediately subjacent the hard mask layer;
an upper MgO layer, subjacent the set of metal layers;
a free layer, subjacent the upper MgO layer;
a lower MgO layer, subjacent the free layer; and
a lower layer stack, including an MTJ layer stack and a bottom electrode layer,
wherein the directing the ion beam and the directing a neutral reactive gas directly to the substrate are performed to etch the set of subjacent layers and at least a portion of the hard mask layer.

7. The method of claim 1, wherein the neutral reactive gas comprises a molecule having a hydroxyl group and given by a formula R—OH, where R is given by CₓH₍₂ₓ₎₊₁.

8. The method of claim 7, wherein a value of x ranges from 1 to 3.

9. The method of claim 1, wherein the ion beam is directed to the substrate at a trajectory forming an angle of incidence with respect to a main plane of the substrate, wherein a value of the angle of incidence ranges from 0 degrees to 90 degrees.

10. The method of claim 1, wherein the at least one metal layer comprises a bottom electrode including tantalum, and wherein the ion beam comprises Kr ions.

11. The method of claim 1, wherein the neutral reactive gas is directed to the substrate concurrently with directing the ion beam to the substrate.

12. A method of etching a magnetic memory, comprising:
providing a substrate in a process chamber, the substrate comprising an array of patterned features, arranged within a magnetic layer stack, the magnetic layer stack including at least one metal layer;
directing an ion beam to the substrate from an ion source, wherein the ion beam causes a physical sputtering of the at least one metal layer; and
directing a neutral reactive gas directly to the substrate, separately from the ion source, wherein the neutral reactive gas reacts with metallic species generated by the physical sputtering of the at least one metal layer.

13. The method of claim 12, wherein the neutral reactive gas reacts with redeposited metallic material that is sputtered from the at least one metal layer, and redeposited on a sidewall of the array of patterned features, wherein the redeposited metallic material is oxidized to form an insulating coating.

14. The method of claim 12, wherein the at least one metal layer comprises tantalum, wherein the neutral reactive gas reacts with redeposited tantalum that is sputtered by the ion beam, and redeposited on a sidewall of the array of patterned features, wherein the redeposited tantalum to form a tantalum oxide coating.

15. The method of claim 12, wherein the neutral reactive gas comprises a molecule having a hydroxyl group and given by a formula R—OH, where R is given by CₓH(₍₂ₓ₎₊₁.

16. The method of claim 12, wherein the ion beam is directed to the substrate at a trajectory forming an angle of incidence with respect to a main plane of the substrate, wherein a value of the angle of incidence ranges from 0 degrees to 90 degrees.

17. The method of claim 12, wherein the magnetic layer stack comprises:
a mask layer, an upper electrode layer, a free layer, a reference layer and a bottom electrode layer.

18. A method of etching a magnetic memory, comprising:
providing a substrate in a process chamber, the substrate comprising an array of patterned features, arranged within a magnetic layer stack, the magnetic layer stack including at least one metal layer;
extracting an ion beam and directing the ion beam to the substrate from an ion source, wherein the ion beam causes a physical sputtering of the at least one metal layer, at a non-zero angle of incidence with respect to a perpendicular to a main plane of the substrate; and
directing a neutral reactive gas directly to the substrate, separately from the ion source, and concurrently with the directing the ion beam, wherein the neutral reactive gas reacts with metallic species generated by the physical sputtering of the at least one metal layer.

19. The method of claim 18, wherein the array of patterned features comprises a plurality of MRAM cells, wherein a given MRAM cell comprises at least one upper metal layer and at least one lower metal layer, separated from the upper metal layer by an insulator layer,
wherein the neutral reactive gas reacts with redeposited metallic material that is sputtered from the lower metal layer, and redeposited on a sidewall of the given MRAM cell, and wherein the redeposited metallic material is oxidized to form an insulating coating abutting the upper metal layer, the insulator layer, and the lower metal layer.

20. The method of claim 18, wherein the magnetic layer stack comprises:
a hard mask layer and a set of subjacent layers, the set of subjacent layers comprising:
a set of metal layers, disposed immediately subjacent the hard mask layer;
an upper MgO layer, subjacent the set of metal layers;
a free layer, subjacent the upper MgO layer;
a lower MgO layer, subjacent the free layer; and
a lower layer stack, including an MTJ layer stack and a bottom electrode,
wherein the directing the ion beam and the directing a neutral reactive gas directly to the substrate are performed to etch the set of subjacent layers and at least a portion of the hard mask layer.
